(19) United States
(12) Patent Application Publication
(10) Pub. No.: US 2022/0352916 A1
(43) Pub. Date: Nov. 3, 2022

(54) RADIO RECEPTION CONTROL DEVICE, RADIO RECEPTION DEVICE, AND RADIO RECEPTION CONTROL METHOD

(71) Applicant: Mitsubishi Electric Corporation, Tokyo (JP)

(72) Inventor: Yozo KANAYAMA, Tokyo (JP)

(73) Assignee: Mitsubishi Electric Corporation, Tokyo (JP)

(21) Appl. No.: 17/426,015

(22) PCT Filed: Feb. 18, 2019
(86) PCT No.: PCT/JP2019/005797

§ 371 Date: Jul. 27, 2021

(51) Int. Cl. H04B 1/16; H04B 1/12

(52) U.S. Cl. CPC H04B 1/16; H04B 1/123

(57) ABSTRACT

A data processing unit creates a database for electric field levels of predetermined frequency bands received by a second tuner. An interfering station determination unit determines whether or not there are a first interfering station and a second interfering station to generate intermodulation interference of third-order distortion with respect to a specific receiving station. A gain calculation unit calculates, as a gain attenuation amount, a difference between at least one of an electric field level of the first interfering station and an electric field level of the second interfering station that are included in the database created by the data processing unit and a reference electric field level at which no intermodulation interference of third-order distortion occurs, the reference electric field level set on the basis of output saturation characteristics of a first high-frequency amplifier inside a first tuner, in a case where the interfering station determination unit determines that there are the first interfering station and the second interfering station. A gain control unit controls the gain of the first high-frequency amplifier using the gain attenuation amount.

### TECHNICAL FIELD

The present invention relates to a radio reception control device, a radio reception device, and a radio reception control method for receiving FM radio broadcast waves.

### BACKGROUND ART

In conventional radio reception devices, automatic gain control of a high-frequency amplifier inside the tuner is adjusted in order to improve the audio quality, when intermodulation interference is detected (see, for example, Patent Literature 1).

### CITATION LIST

### Patent Literature

Patent Literature 1: JP 2014-506746 A

### SUMMARY OF INVENTION

### Technical Problem

The conventional radio reception devices have a disadvantage that output saturation characteristics of a high-frequency amplifier are not considered and thus there are cases where adjustment of automatic gain control at the time when intermodulation interference is detected is inappropriate. In a case where the gain attenuation amount of the high-frequency amplifier is small, intermodulation components remain excessively in an input signal, and in a case where the gain attenuation amount of the high-frequency amplifier is large, the input level of a receiving station that is being listened to is small, and thus the audio quality cannot be sufficiently improved in either case.

The present invention has been made in order to solve the above disadvantage, and an object of the present invention is to perform gain control in consideration of output saturation characteristics of a high-frequency amplifier.

### Solution to Problem

A radio reception control device according to the present invention includes: a data processing unit for creating a database for electric field levels of predetermined frequency bands received by a tuner; an interfering station determination unit for determining whether or not there are a first interfering station and a second interfering station to generate intermodulation interference of third-order distortion with respect to a specific receiving station, among the predetermined frequency bands; a gain calculation unit for calculating, as a gain attenuation amount, a difference between at least one of an electric field level of the first interfering station and an electric field level of the second interfering station that are included in the database created by the data processing unit and a reference electric field level at which no intermodulation interference of third-order distortion occurs, the reference electric field level set on the basis of an output saturation characteristic of a high-frequency amplifier inside the tuner, in a case where the interfering station determination unit determines that there are the first interfering station and the second interfering station; and a gain control unit for controlling a gain of the high-frequency amplifier using the gain attenuation amount calculated by the gain calculation unit.

### Advantageous Effects of Invention

According to the present invention, gain control is performed in consideration of the output saturation characteristics of a high-frequency amplifier, and thus the audio quality can be improved.

### BRIEF DESCRIPTION OF DRAWINGS

FIG. 1 is a hardware configuration diagram of a radio reception device according to a first embodiment.

FIG. 2 is a functional block diagram of the radio reception device according to the first embodiment.

FIG. 3 is a graph illustrating the output saturation characteristics of a high-frequency amplifier.

FIG. 4 is a flowchart illustrating exemplary operation of a radio reception control device according to the first embodiment.

FIG. 5 is a flowchart illustrating exemplary operation of a radio reception control device according to a second embodiment.

### DESCRIPTION OF EMBODIMENTS

To describe the present invention further in detail, embodiments for carrying out the present invention will be described below with reference to the accompanying drawings.

### First Embodiment

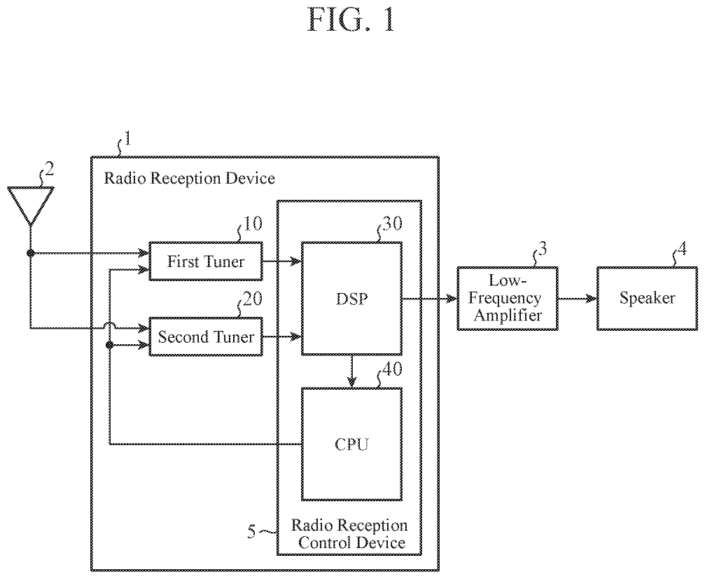

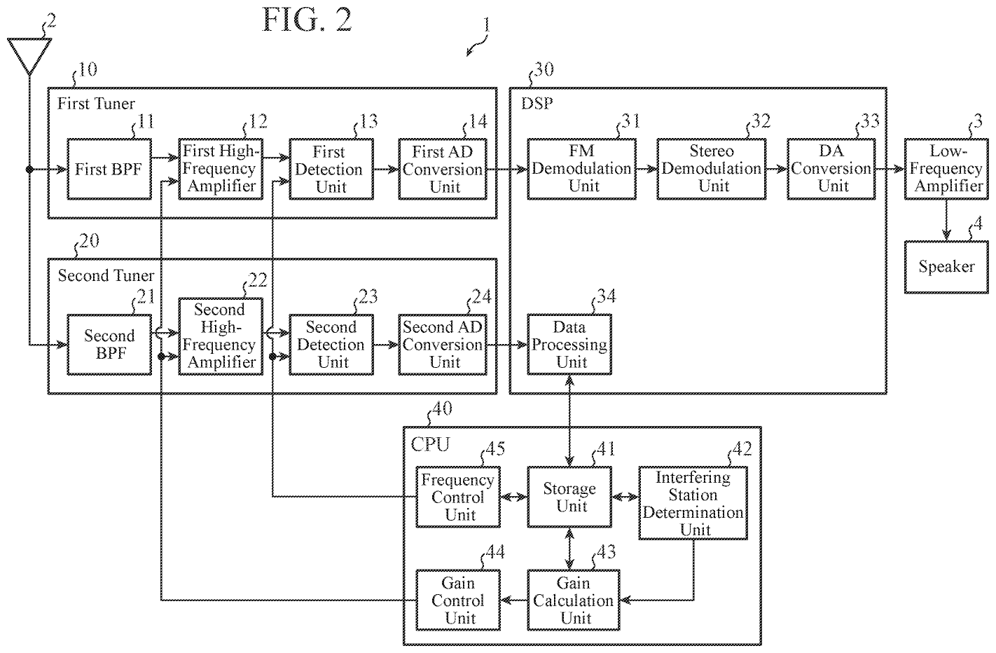

FIG. 1 is a hardware configuration diagram of a radio reception device 1 according to a first embodiment. FIG. 2 is a functional block diagram of the radio reception device 1 according to the first embodiment. The radio reception device 1 is connected with an antenna 2 for receiving a FM radio broadcast wave and a low-frequency amplifier 3 for amplifying an audio signal generated from the FM radio broadcast wave. A speaker 4 outputs the audio signal amplified by the low-frequency amplifier 3 by sound.

The radio reception device 1 includes a first tuner 10, a second tuner 20, a digital signal processor (DSP) 30, and a central processing unit (CPU) 40. The DSP 30 and the CPU 40 are included in a radio reception control device 5.

The first tuner 10 includes a first band pass filter (BPF) 11, a first high-frequency amplifier 12, a first detection unit 13, and a first analog digital (AD) conversion unit 14. The second tuner 20 includes a second BPF 21, a second high-frequency amplifier 22, a second detection unit 23, and a second AD conversion unit 24. The DSP 30 includes an FM demodulation unit 31, a stereo demodulation unit 32, a digital analog (DA) conversion unit 33, and a data processing unit 34. The CPU 40 includes a storage unit 41, an interfering station determination unit 42, a gain calculation unit 43, a gain control unit 44, and a frequency control unit 45.

The functions of the FM demodulation unit 31, the stereo demodulation unit 32, the DA conversion unit 33, and the data processing unit 34 in the DSP 30 are implemented by software, firmware, or a combination of software and firmware. The software or the firmware is described as a program, which is stored in a memory (not illustrated). The DSP 30 reads and executes a program stored in a memory (not illustrated) and thereby implements the functions of the above units.

The functions of the interfering station determination unit 42, the gain calculation unit 43, the gain control unit 44, and the frequency control unit 45 in the CPU 40 are implemented by software, firmware, or a combination of software and firmware. The software or the firmware is described as a program, which is stored in a memory (not illustrated). The CPU 40 reads and executes a program stored in the memory (not illustrated) and thereby implements the functions of the above units.

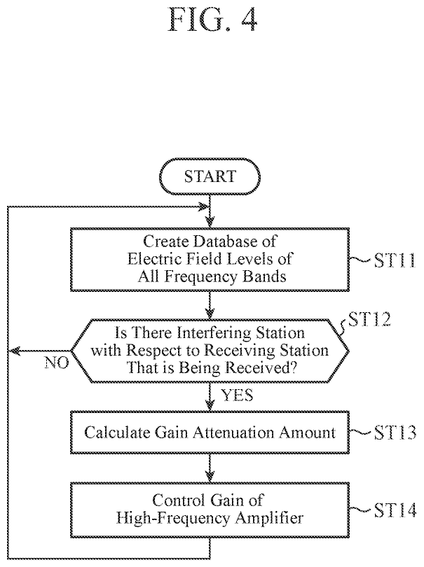

As described above, the radio reception control device 5 includes the memory (not illustrated) for storing a program which, when executed by the DSP 30 and the CPU 40, results in execution of the steps illustrated in the flowchart of FIG. 4 described later. It can also be said that this program causes a computer to execute the procedures or methods performed in the FM demodulation unit 31, the stereo demodulation unit 32, the DA conversion unit 33, the data processing unit 34, the interfering station determination unit 42, the gain calculation unit 43, the gain control unit 44, and the frequency control unit 45.

Next, the details of the radio reception device 1 will be described with reference to FIG. 2.

The first tuner 10 is for receiving from a specific receiving station (hereinafter, referred to as “receiving station”) that a listener desires to listen to. The first BPF 11 passes all the frequency bands of the FM radio broadcasting (for example, 76.0 MHz to 109.0 MHz) out of high frequency signals output from the antenna 2. The first high-frequency amplifier 12 amplifies the high frequency signals that have passed through the first BPF 11 with a gain controlled by the gain control unit 44. The first detection unit 13 detects the high frequency signals amplified by the first high-frequency amplifier 12, on the basis of the frequency of a receiving station on which an instruction is given by the frequency control unit 45, and outputs a signal of the receiving station. The first AD conversion unit 14 converts the signal of the receiving station into a digital signal and outputs the signal to the FM demodulation unit 31.

The FM demodulation unit 31 performs demodulation processing on the digital signal of the receiving station that is output from the first AD conversion unit 14, and outputs a stereo composite signal. The stereo demodulation unit 32 performs demodulation processing using the stereo composite signal output from the FM demodulation unit 31, and outputs an audio signal of a right channel and an audio signal of a left channel. The DA conversion unit 33 converts the audio signal of the right channel and the audio signal of the left channel into analog signals, and outputs the analog signals to the low-frequency amplifier 3.

The second tuner 20 is for repeating a search for grasping the radio wave condition of all the frequency bands of the FM radio broadcasting and creating a database. The second BPF 21 passes all the frequency bands of the FM radio broadcasting out of high frequency signals output from the antenna 2. The second high-frequency amplifier 22 amplifies the high frequency signals that have passed through the second BPF 21 with a gain controlled by the gain control unit 44. The second detection unit 23 detects the high frequency signals amplified by the second high-frequency amplifier 22, on the basis of the frequency to be searched for on which an instruction is given by the frequency control unit 45, and outputs a signal of the frequency to be searched for. The second AD conversion unit 24 converts the signal of the frequency to be searched for into a digital signal, and outputs the digital signal to the data processing unit 34.

The data processing unit 34 stores, in the storage unit 41, the electric field level of the signal of the frequency to be searched for that is output from the second AD conversion unit 24. The data processing unit 34 generates a database, by storing the electric field levels of all frequency bands in the storage unit 41.

The storage unit 41 stores a database which is generated by the data processing unit 34 and which represents the electric field level of each frequency of all the frequency bands of the FM radio broadcasting. The storage unit 41 also stores, in advance, both information on the reference electric field level at which no intermodulation interference of third-order distortion occurs, and which is set on the basis of the output saturation characteristics of the first high-frequency amplifier 12, and information on the lowest electric field level at which the audio quality can be ensured.

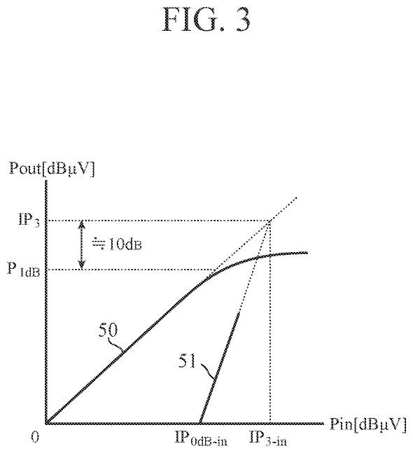

FIG. 3 is a graph illustrating the output saturation characteristics of the first high-frequency amplifier 12. Value Pin on the horizontal axis represents the electric field level of a high frequency signal input from the antenna 2 to the first high-frequency amplifier 12 (hereinafter referred to as “input level”), and value Pout on the vertical axis represents the electric field level of a high frequency signal output by the first high-frequency amplifier 12 (hereinafter referred to as “output level”). An output level 50 for the input level of the receiving station increases linearly up to Pi as and is saturated above that value.

An output level 51 of an intermodulation component of third-order distortion increases in proportion to three times the output level 50 of the receiving station. This proportional relationship applies to a case of logarithmic notation and, in antilogarithm, is expressed by the third power. For example, when the output level 50 of the receiving station is increased ten times, the output level 51 of the intermodulation component of third-order distortion that is generated accordingly increases 1000 times. In order to suppress the output level 51 of an intermodulation component of third-order distortion, the means that can be taken is either to use the first high-frequency amplifier 12 having a high IP₃ (third order intercept point) or to suppress the output level 50 of the receiving station by controlling the gain of the first high-frequency amplifier 12. In the first embodiment, the gain of the first high-frequency amplifier 12 is controlled. Value IP_{0 dB-in} in the output saturation characteristic of FIG. 3 is stored in advance in the storage unit 41, as the “reference electric field level” at which no intermodulation interference of third-order distortion occurs.

The frequency control unit 45 refers to the storage unit 41, and in a case where the electric field level of a receiving station that a listener desires to listen to is higher than or equal to the minimum electric field level that can ensure the audio quality, the frequency control unit 45 instructs the first detection unit 13 on the frequency of the receiving station. On the other hand, in a case where the electric field level of the receiving station is less than the minimum electric field level, the frequency control unit 45 determines that there is no FM radio broadcast wave at the frequency of the receiving station or that the audio quality cannot be ensured. Then, the frequency control unit 45 excludes the receiving station from tuning targets and does not instruct the first detection unit 13 on the frequency.

The frequency control unit 45 repeatedly performs a search for grasping the radio wave condition in all the frequency bands in parallel with tuning of the receiving station. The frequency control unit 45 instructs the second detection unit 23 on each frequency of all the frequency bands one by one. Every time the second detection unit 23 changes a frequency to be searched for in accordance with the instruction of the frequency control unit 45, the signal of the frequency to be searched for is output to the data processing unit 34 via the second detection unit 23 and the second AD conversion unit 24. Since the radio wave condition of the FM radio broadcasting fluctuates from time to time, the data processing unit 34 updates the electric field level of a frequency to be searched for that is stored in the storage unit 41 each time the frequency to be searched for is received by the second tuner 20.

The interfering station determination unit 42 refers to the storage unit 41, determines whether or not there are a first interfering station and a second interfering station to generate intermodulation interference of third-order distortion with respect to the receiving station that the first tuner 10 is receiving from, and outputs the determination result to the gain calculation unit 43. In a case where the interfering station determination unit 42 determines that there are the first interfering station and the second interfering station, the gain calculation unit 43 calculates the gain attenuation amount of the first high-frequency amplifier 12 so that the electric field levels of the first interfering station and the second interfering station drop to the reference electric field level (IP_{0 dB-in} in FIG. 3). The gain calculation unit 43 outputs a difference from the reference electric field level that has been calculated, to the gain control unit 44 as a gain attenuation amount. The gain control unit 44 controls the gain of the first high-frequency amplifier 12 using the gain attenuation amount calculated by the gain calculation unit 43. Meanwhile, the gain control unit 44 does not perform control using the gain attenuation amount on the second high-frequency amplifier 22 and gives an instruction on a predetermined gain.

FIG. 4 is a flowchart illustrating exemplary operation of the radio reception control device 5 according to the first embodiment. The radio reception control device 5 starts the operation illustrated in the flowchart of FIG. 4 when the power of the radio reception device 1 is turned on, and ends the operation when the power of the radio reception device 1 is turned off.

In step ST11, the data processing unit 34 creates the database for the electric field level of each frequency of all the frequency bands of the FM radio broadcasting using the signals of the frequencies to be searched for that are output from the second tuner 20, and stores the database in the storage unit 41.

In step ST12, the interfering station determination unit 42 refers to the storage unit 41, and determines whether or not there are a first interfering station and a second interfering station to generate intermodulation interference of third-order distortion with respect to the receiving station that the first tuner 10 is receiving from. If a first interfering station and a second interfering station exist (“YES” in step ST12), the processing proceeds to step ST13, and if there are no first interfering station and second interfering station (“NO” in step ST12), the processing returns to step ST11.

The interfering station determination unit 42 determines a frequency f1 of the first interfering station and a frequency f2 of the second interfering station with respect to a frequency f0 of the receiving station, the frequencies f1 and f2 satisfying either one of the following Equations 1 or 2.

f0=2×f1−f2 (1)

f0=2×f2−f1 (2)

For example, let us assume that the frequency f0 of the receiving station is “96.0 MHz”. In this case, the interfering station determination unit 42 determines “98.1 MHz” as the frequency f1 of the first interfering station and “100.2 MHz” as the frequency f2 of the second interfering station, the frequencies f1 and f2 satisfying Equation 1.

In step ST13, the gain calculation unit 43 calculates, as the gain attenuation amount, a difference between at least one of the electric field level of the first interfering station and the electric field level of the second interfering station and the reference electric field level, the electric field levels and the reference electric field levels being stored in the storage unit 41.

For example, it is assumed that the electric field level of the first interfering station is “100 dBμV”, the electric field level of the second interfering station is “100 dBμV”, and the reference electric field level is “60 dBμV”. In this case, the gain calculation unit 43 calculates “40 dBμV” (=100 dBμV−60 dBμV) as the gain attenuation amount.

Note that, in a case where the electric field level of the first interfering station and the electric field level of the second interfering station are different, the gain calculation unit 43 is only required to calculate the gain attenuation amount using at least one of the electric field level of the first interfering station and the electric field level of the second interfering station.

For example, it is assumed that the electric field level of the first interfering station is “90 dBμV”, that the electric field level of the second interfering station is “70 dBμV”, and that the reference electric field level is “60 dBμB”. In this case, the gain calculation unit 43 uses a difference of “30 dBμV” between the larger electric field level “90 dBμV” and the reference electric field level “60 dBμV”, as the gain attenuation amount. Alternatively, the gain calculation unit 43 may use a difference of “20 dBμV” between an average value “80 dBμV” (=(90 dBμV+70 dBμV)/2) of the electric field level of the first interfering station and the electric field level of the second interfering station and the reference electric field level “60 dBμV”, as the gain attenuation amount.

In step ST14, the gain control unit 44 attenuates the gain of the first high-frequency amplifier 12 by the gain attenuation amount calculated by the gain calculation unit 43. As a result, the intermodulation interference of third-order distortion with respect to the receiving station is suppressed, and thus the audio quality of the receiving station is improved.

The second tuner 20 repeats the search for grasping the radio wave condition in all the frequency bands in accordance with the instruction of the frequency control unit 45. Therefore, in the next step ST11, the data processing unit 34 updates the electric field level of each frequency of all the frequency bands of the FM radio broadcasting included in the database in the storage unit 41. In the following steps ST12 to ST14, the processing using the updated electric field level is performed.

As described above, the radio reception control device 5 according to the first embodiment includes the data processing unit 34, the interfering station determination unit 42, the gain calculation unit 43, and the gain control unit 44. The data processing unit 34 creates a database for electric field levels of all the frequency bands of the FM radio broadcasting received by the second tuner 20. The interfering station determination unit 42 determines whether or not there are a first interfering station and a second interfering station to generate intermodulation interference of third-order distortion with respect to the receiving station that the first tuner 10 is receiving from, among all the frequency bands of the FM radio broadcasting. In a case where the interfering station determination unit 42 determines that there are the first interfering station and the second interfering station, the gain calculation unit 43 calculates, as the gain attenuation amount, a difference between at least one of the electric field level of the first interfering station and the electric field level of the second interfering station that are included in the database created by the data processing unit 34 and the reference electric field level at which no intermodulation interference of third-order distortion occurs, and which is set on the basis of output saturation characteristics of the first high-frequency amplifier 12 inside the first tuner 10. The gain control unit 44 controls the gain of the first high-frequency amplifier 12 using the gain attenuation amount calculated by the gain calculation unit 43. In this manner, the radio reception control device 5 can suppress intermodulation interference of third-order distortion with respect to the receiving station that a listener is listening to, by performing gain control in consideration of output saturation characteristics of the first high-frequency amplifier 12, and thus it is possible to improve the audio quality of the receiving station.

Moreover, in a case where the electric field level of the first interfering station and the electric field level of the second interfering station are different, the gain calculation unit 43 of the first embodiment calculates, as the gain attenuation amount, a difference between an average value of the electric field level of the first interfering station and the electric field level of the second interfering station and the reference electric field level. With this configuration, even in a case where the electric field level of the first interfering station and the electric field level of the second interfering station are different, the radio reception control device 5 can improve the audio quality of the receiving station, by performing gain control in consideration of the output saturation characteristics of the first high-frequency amplifier 12.

Furthermore, the radio reception device 1 according to the first embodiment includes the radio reception control device 5, the first tuner 10 used for reception from a receiving station, and the second tuner 20 used for creating, by the data processing unit 34, the database for the electric field levels of all the frequency bands. With this configuration, the radio reception control device 5 can update the electric field level that fluctuates from time to time, by using the second tuner 20, and thus the gain of the first high-frequency amplifier 12 in the first tuner 10 can be optimally controlled as required. Therefore, the radio reception device 1 is particularly suitable for a radio reception device 1 mounted on or brought into a mobile object such as a vehicle.

Note that although the radio reception device 1 according to the first embodiment includes the first tuner 10 and the second tuner 20, a configuration including a single tuner may be adopted. In this case, the radio reception device 1 is only required to use a single tuner as the first tuner 10 when a listener desires to listen to a receiving station and to use the single tuner as the second tuner 20 in other periods, for example.

Alternatively, the radio reception device 1 may detect a moment when there is no audio output while a single tuner is receiving from the receiving station that the listener desires to listen to, switch, at the detected moment, the single tuner to the frequency of the first interfering station and the frequency of the second interfering station to acquire the electric field level of each of the frequencies, and update the database in the storage unit 41.

### Second Embodiment

The configuration of a radio reception device 1 according to a second embodiment is the same as that illustrated in FIGS. 1 and 2 of the first embodiment in the drawings, and thus FIGS. 1 and 2 are referred to hereinbelow.

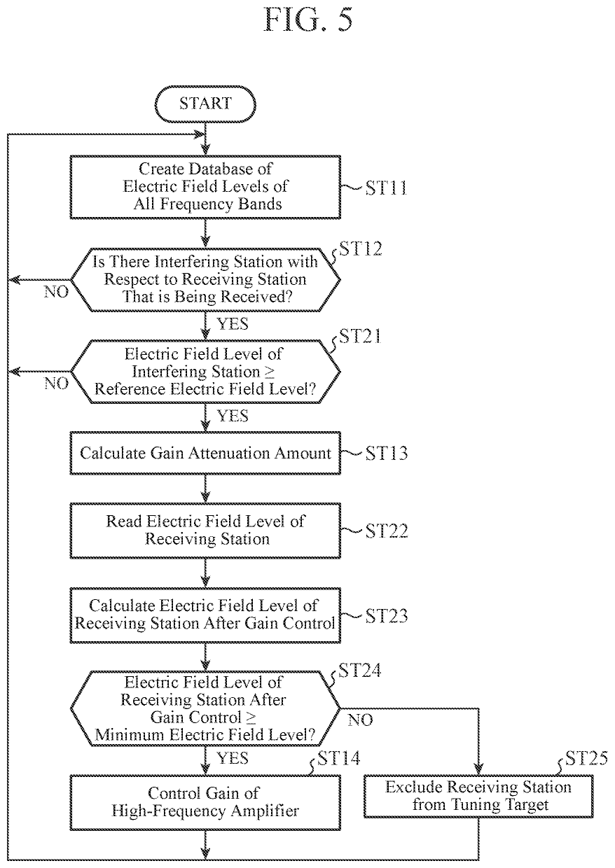

FIG. 5 is a flowchart illustrating exemplary operation of the radio reception control device 5 according to the second embodiment. The radio reception control device 5 starts the operation illustrated in the flowchart of FIG. 5 when the power of the radio reception device 1 is turned on, and ends this operation when the power of the radio reception device 1 is turned off. The operation in steps ST11 to ST14 in FIG. 5 is the same as the operation in steps ST11 to ST14 in FIG. 4.

The intermodulation interference of third-order distortion with respect to a receiving station occurs in a case where there are two interfering stations each having a large electric field level. Therefore, in step ST21, the interfering station determination unit 42 determines whether or not the electric field level of the first interfering station and the electric field level of the second interfering station are higher than or equal to the reference electric field level. If the electric field level of the first interfering station and the electric field level of the second interfering station are higher than or equal to the reference electric field level (“YES” in step ST21), the processing proceeds to step ST13. On the other hand, if at least one of the electric field level of the first interfering station and the electric field level of the second interfering station is less than the reference electric field level (“NO” in step ST21), the processing returns to step ST11. Therefore, the gain control unit 44 does not control the gain of the first high-frequency amplifier 12 in a case where at least one of the electric field level of the first interfering station and the electric field level of the second interfering station is less than the reference electric field level.

In step ST22, the gain calculation unit 43 reads the electric field level of the receiving station from the storage unit 41. In step ST23, the gain calculation unit 43 calculates, as the electric field level of the receiving station when the gain attenuation amount calculated in step ST13 is applied to the first high-frequency amplifier 12 (hereinafter referred to as “electric field level of the receiving station after gain control”), a difference between the electric field level of the receiving station read from the storage unit 41 and the gain attenuation amount.

In step ST24, the gain calculation unit 43 determines whether or not the electric field level of the receiving station after the gain control is higher than or equal to the minimum electric field level at which the audio quality can be ensured. It is assumed that the minimum electric field level is stored in the storage unit 41 in advance. If the electric field level of the receiving station after the gain control is higher than or equal to the minimum electric field level (“YES” in step ST24), the gain calculation unit 43 outputs the gain attenuation amount calculated in step ST13 to the gain control unit 44. In the following step ST14, the gain control unit 44 controls the gain of the first high-frequency amplifier 12 using the gain attenuation amount from the gain calculation unit 43. On the other hand, if the electric field level of the receiving station after the gain control is less than the minimum electric field level (“NO” in step ST24), the processing proceeds to step ST25. Therefore, the gain control unit 44 does not control the gain of the first high-frequency amplifier 12 when the electric field level of the receiving station after the gain control is less than the minimum electric field level.

In step ST25, the gain calculation unit 43 excludes the receiving station from tuning targets. Specifically, the gain calculation unit 43 stores, in the storage unit 41, information indicating that the receiving station is not a tuning target. When instructing the first detection unit 13 of the first tuner 10 on the frequency of the receiving station, the frequency control unit 45 confirms whether or not information indicating that this receiving station is not a tuning target is stored in the storage unit 41. In a case where the receiving station is not a tuning target, the frequency control unit 45 does not instruct the first detection unit 13 on the frequency.

For example, let us assume that the electric field level of the receiving station is “70 dBμV”, the gain attenuation amount is “40 dBμV”, and the minimum electric field level is “20 dBμV”. In this case, the gain calculation unit 43 assumes that the gain of the first high-frequency amplifier 12 has been attenuated by “40 dBμV” by the gain control unit 44, and thus calculates the electric field level of the receiving station after the gain control, as “30 dBμV” (=70 dBμV−40 dBμV). Since the electric field level of “30 dBμV” of the receiving station after the gain control is higher than or equal to the minimum electric field level of “20 dBμV”, the gain control unit 44 attenuates the gain of the first high-frequency amplifier 12 by “40 dBμV”.

Note that, in a case where the gain calculation unit 43 has previously excluded this receiving station from the tuning target, the gain calculation unit 43 returns this receiving station to a tuning target. Specifically, the gain calculation unit 43 erases, from the storage unit 41, information indicating that the receiving station is not a tuning target.

Alternatively, for example, it is assumed that the electric field level of the receiving station is “50 dBμV”, the gain attenuation amount is “40 dBμV”, and the minimum electric field level is “20 dBμV”. In this case, the gain calculation unit 43 assumes that the gain of the first high-frequency amplifier 12 has been attenuated by “40 dBμV” by the gain control unit 44, and thus calculates the electric field level of the receiving station after the gain control, as “10 dBμV” (=50 dBμV−40 dBμV). Since the electric field level of “10 dBμV” of the receiving station after the gain control is less than the minimum electric field level of “20 dBμV”, the gain calculation unit 43 excludes the receiving station from the tuning target of the frequency control unit 45.

As described above, in a case where the electric field level of a receiving station when it is assumed that the gain of the first high-frequency amplifier 12 has been controlled by the gain control unit 44 is less than a predetermined minimum electric field level, the gain calculation unit 43 of the second embodiment excludes the receiving station from the tuning target. With this configuration, in a case where the audio quality of a receiving station cannot be ensured even when gain control in consideration of the output saturation characteristics of the first high-frequency amplifier 12 is performed, the radio reception control device 5 can exclude the receiving station from the tuning target and thus prevent a listener from listening from the receiving station.

Furthermore, the gain control unit 44 of the second embodiment does not control the gain of the first high-frequency amplifier 12, in a case where at least one of the electric field level of the first interfering station and the electric field level of the second interfering station is less than the reference electric field level. Since the radio reception control device 5 does not change the gain of the first high-frequency amplifier 12 when no intermodulation interference of third-order distortion with respect to a receiving station occurs, it is possible to prevent fluctuations in the audio quality of a receiving station that is being listened to.

Note that the present invention may include a flexible combination of the embodiments, a modification of any component of the embodiments, or omission of any component in the embodiments within the scope of the present invention.

### INDUSTRIAL APPLICABILITY

A radio reception device according to the present invention is particularly suitable for a radio reception device for mobile objects, since the audio quality is improved in consideration of the radio wave condition and the output saturation characteristics of a high-frequency amplifier.

### REFERENCE SIGNS LIST

1: radio reception device, 2: antenna, 3: low-frequency amplifier, 4: speaker, 5: radio reception control device, 10: first tuner, 11: first BPF, 12: first high-frequency amplifier, 13: first detection unit, 14: first AD conversion unit, 20: second tuner, 21: second BPF, 22: second high-frequency amplifier, 23: second detection unit, 24: second AD conversion unit, 30: DSP, 31: FM demodulation unit, 32: stereo demodulation unit, 33: DA conversion unit, 34: data processing unit, 40: CPU, 41: storage unit, 42: interfering station determination unit, 43: gain calculation unit, 44: gain control unit, 45: frequency control unit, 50: receiving station output level, 51: output level of intermodulation component of third-order distortion

1. A radio reception control device comprising:
first processing circuitry to create a database for electric field levels of predetermined frequency bands received by a tuner; and
second processing circuitry
to determine whether or not there are a first interfering station and a second interfering station to generate intermodulation interference of third-order distortion with respect to a specific receiving station, among the predetermined frequency bands;
to calculate, as a gain attenuation amount, a difference between at least one of an electric field level of the first interfering station and an electric field level of the second interfering station that are included in the database created by the first processing circuitry and a reference electric field level at which no intermodulation interference of third-order distortion occurs, the reference electric field level set on a basis of an output saturation characteristic of a high-frequency amplifier inside the tuner, in a case where it is determined that there are the first interfering station and the second interfering station; and
to control a gain of the high-frequency amplifier using the calculated gain attenuation amount.

2. The radio reception control device according to claim 1, wherein the second processing circuitry excludes the receiving station from a tuning target, in a case where an electric field level of the receiving station when it is assumed that the gain of the high-frequency amplifier has been controlled by the second processing circuitry is less than a predetermined minimum electric field level.

3. The radio reception control device according to claim 1, wherein the second processing circuitry does not control the gain of the high-frequency amplifier, in a case where at least one of the electric field level of the first interfering station and the electric field level of the second interfering station is less than the reference electric field level.

4. The radio reception control device according to claim 1, wherein the second processing circuitry calculates, as the gain attenuation amount, a difference between an average value of the electric field level of the first interfering station and the electric field level of the second interfering station and the reference electric field level, in a case where the electric field level of the first interfering station and the electric field level of the second interfering station are different.

5. A radio reception device comprising:
the radio reception control device according to claim 1; and
the tuner including the high-frequency amplifier.

6. The radio reception device according to claim 5,
wherein the tuner includes:
a first tuner used for reception from the receiving station; and
a second tuner used for, by the first processing circuitry, creating the database for the electric field levels of the predetermined frequency bands.

7. A radio reception control method comprising:
creating a database for electric field levels of predetermined frequency bands received by a tuner;
determining whether or not there are a first interfering station and a second interfering station to generate intermodulation interference of third-order distortion with respect to a specific receiving station, among the predetermined frequency bands;
calculating, as a gain attenuation amount, a difference between at least one of an electric field level of the first interfering station and an electric field level of the second interfering station that are included in the created database and a reference electric field level at which no intermodulation interference of third-order distortion occurs, the reference electric field level set on a basis of an output saturation characteristic of a high-frequency amplifier inside the tuner, in a case where it is determined that there are the first interfering station and the second interfering station; and
controlling a gain of the high-frequency amplifier using the calculated gain attenuation amount.
